(19) United States
(12) Patent Application Publication
(10) Pub. No.: US 2008/0190765 A1
(43) Pub. Date: Aug. 14, 2008

(54) Sputtering Magnetron

(75) Inventors: Andreas Lopp, Freigericht-Somborn (DE); Manfred Ruske, Kerpen (DE)

Correspondence Address: PATTERSON & SHERIDAN, L.L.P., 3040 POST OAK BOULEVARD, SUITE 1500, HOUSTON, TX, 77056, US

(73) Assignee: Applied Materials GmbH & Co.KG, Alzenau (DE)

(21) Appl. No.: 11/914,935

(22) PCT Filed: Jun. 4, 2005
(86) PCT No.: PCT/EP2005/006032

§ 371 Date: Feb. 19, 2008

(51) Int. Cl. C23C 14/35

(52) U.S. Cl. 204/298.16

(57) ABSTRACT

The invention relates to a magnetron with a planar target and a planar magnet system. The planar magnet system comprises a bar-shaped first magnet pole with enlarged ends and a frame-shaped second magnet pole, wherein a relative movement between the magnet poles and the target is such that every point of the magnet system moving with the target being stationary moves on a circular path. If the magnet system is stationary, each point of the target moves on such a circular path. During the relative movement with respect to one another the magnet system and the target are in parallel planes. The diameter of the circular path corresponds to the mean distance between two parallel arms of a plasma tube, which during the sputter operation develops between the first and the second magnet pole. Thereby that the magnets in the curve region of the plasma tube are disposed such that the pole lines form at this site a circle arc or a circular area, holes in the target are avoided.

### OBJECTIVE

Coating of substrates with a thin material layer or with several thin material layers plays an important role in numerous technical fields.

For example CD disks can be provided with a protective layer or clock housings with a ceramic layer. Coating glass with layers which permit only certain wavelengths to pass or reflect them has gained considerable significance. Large glass facades are installed on buildings with so-called architectural glass provided with thin layers. The coating can also serve for the purpose of making synthetic films or synthetic bottles gas-tight.

### PRIOR ART

The method very often employed for coating the listed materials is the sputtering method. In the sputtering method a plasma is generated in an evacuated chamber. By plasma is understood a mixture of positive and negative charge carriers at relatively high density and of neutral particles as well as photons. The positive ions of the plasma are attracted by the negative potential of the cathode, which is provided with a so-called target. When the positive ions of the plasma impinge on the target, they knock small particles out of it, which, in turn, can be deposited on the substrate disposed opposite the target. This knocking-out of particles is referred to as “sputtering”. One differentiates here between reactive and non-reactive sputtering. In non-reactive sputtering the work proceeds with inert gases, which serve as working gas and their positive gas ions knock particles out of the target. The reactive sputtering additionally employs reactive gases, for example oxygen, which form a compound with the particles of the target before they are deposited on a substrate.

The ions required for the sputtering process are generated by the collisions of gas atoms and electrons, for example in a glow discharge, and with the aid of an electric field accelerated into the target forming the cathode.

The free electrons are primarily responsible for the ionization. These can be densified in front of a target with the aid of magnets and therewith intensify the ionization. The combination of cathode and magnets is referred to as a magnetron.

A problem encountered in magnetrons lies therein that the target material is only eroded non-uniformly since the magnetic field is not homogeneous. For example, in the proximity of the pole lines of the magnetic fields no erosion of the target material occurs. As pole lines are denoted those zones in which the magnetic field lines penetrate perpendicularly the target surface on the sputter side. As a consequence of the non-uniform erosion of the target material, the substrate is also coated non-uniformly.

The aim is therefore to eliminate the disadvantage of the non-uniform erosion.

A magnetron is already known in which a magnet system is moved parallel to the target material (EP 1 120 811 A2). The magnet system involves several magnets, which are moved on a path relative to and parallel with the target surface. Through this magnet system the magnetic field becomes more homogeneous and the uniform erosion of the target material is ensured.

A high target utilization can also be attained thereby that a tubular target is employed. In this target is located a magnet system, which is moved relative to the target, or the magnet system is stationary while the tubular target is moved about the magnet system (DE 41 17 367 C2).

Lastly is also known a planar magnetron comprising several magnets, which define a magnetic field in the form of a closed loop in order to generate a plasma tube over a target (EP 0 918 351 A1). Herein devices are provided which cause a cyclical movement between the magnets and the surface of the target. One of these movements is circular.

Problem

The invention addresses the problem of improving the utilization of a planar and rectangular target in the sputter process.

Resolution of the Problem

The problem is solved according to the characteristics of patent claim 1.

The invention consequently relates to a magnetron with a planar target and a planar magnet system. The planar magnet system comprises a bar-shaped first magnetic pole with enlarged ends and a frame-shaped second magnetic pole and a relative movement between the magnetic poles and the target proceeds in such a manner that, in the case of a stationary target, each moving point of the magnetic system moves on a circular path. If the magnet system is stationary, each point of the target moves on such a circular path. During the relative movement with respect to one another the magnet system and the target are in parallel planes. The diameter of the circular path corresponds to the mean distance between two parallel arms of a plasma tube, which develops between the first and the second magnetic pole during the sputtering operation. Thereby that the magnets in the curve region of the plasma tube are disposed such that the pole lines form in this region a circular arc or a circular area, holes in the target are avoided.

### ADVANTAGES OF THE INVENTION

The advantage attained with the invention comprises in particular that the target is also sputtered at those sites at which the magnetic field lines in static operation penetrate perpendicularly through the target surface. In particular the increased erosion rates occurring on a narrow side of a rectangular target are avoided.

### BRIEF DESCRIPTION OF THE DRAWING

Embodiment examples of the invention are shown in the drawing and will be described in further detail in the following. In the drawing depict:

FIG. 1 a magnet configuration with inner and outer magnet and a plasma tube,

FIG. 2 a magnet configuration movable above a target,

FIG. 3 a magnet configuration with plasma tube, in which the inner magnet is broadened at its end,

FIG. 4 a plasma tube with circular integration contours,

FIG. 5 a magnet configuration with broadened ends of the inner magnets, the broadening-out being realized through magnets disposed in parallel,

FIG. 6 a magnet configuration with broadened-out ends of the inner magnets, the broadening-out being realized by ring magnets,

FIG. 7 a magnet configuration with broadened ends of the inner magnets, the broadening-out being realized by round disks,

FIG. 8 a drive for driving the magnet configuration relative to a target.

### DESCRIPTION OF EMBODIMENTS

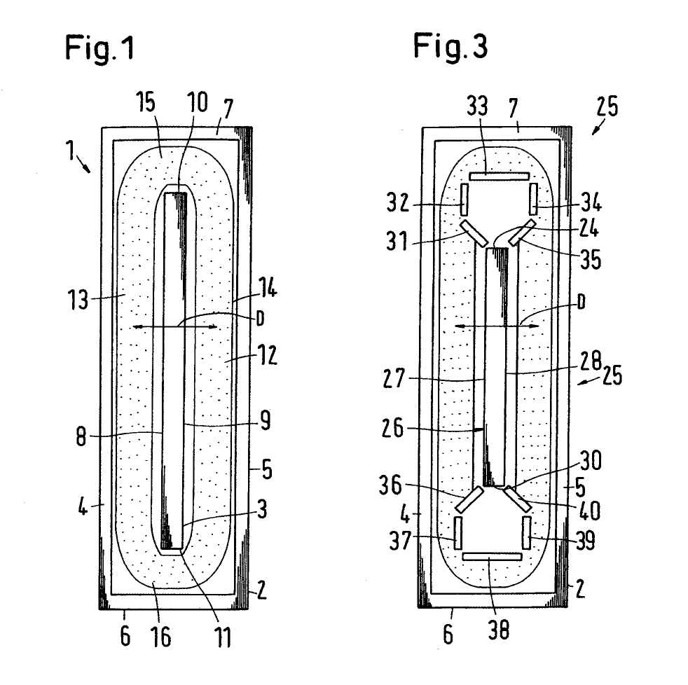

FIG. 1 depicts a magnet configuration 1 such as is utilized in the sputtering of planar targets. Such a magnet configuration is depicted for example in FIG. 10 of U.S. Pat. No. 5,382,344.

The magnet configuration 1 is comprised of a first magnet pole, for example a north pole 2 and a second magnet pole, for example a south pole 3. The north pole 2 has the form of a rectangular frame encompassing the bar-shaped south pole 3.

The north pole 2 is comprised of two long sides 4, 5 and two short sides 6, 7. The south pole 3 also has two long sides 8, 9 and two short sides 10, 11, the short sides 10, 11, however, being considerable shorter than the short sides 6, 7 of the north pole 2.

Between the north pole 2 and the south pole 3 is evident a plasma tube 12, which occupies nearly the entire interspace between north pole 2 and south pole 3. This plasma tube 12 results from the magnetic field of the magnet configuration 1 in connection with a voltage applied on a cathode not shown in FIG. 1, this cathode being connected to the magnet configuration 1. North pole 2 and south pole 3 are coupled with one another via a yoke.

The target, also not shown in FIG. 1, is at least of the same size as the magnet configuration 1 and is disposed parallel with it. Consequently, the magnet configuration 1 and the target are in parallel planes.

The plasma tube 12 can be subdivided into four regions. Two regions 13, 14 extend parallel to the long sides 4, 5 of the north pole 2, while two other regions 15, 16 encompass semi-elliptically the ends of the south pole 3.

D denotes the distance between the center lines of the parallel regions 13, 14 of the plasma tube 12.

If the magnet configuration 1 is employed in a magnetron, during static operation substantially sputtered off are those portions of the target which are located directly opposite to the plasma tube 12. The remaining areas are substantially not eroded.

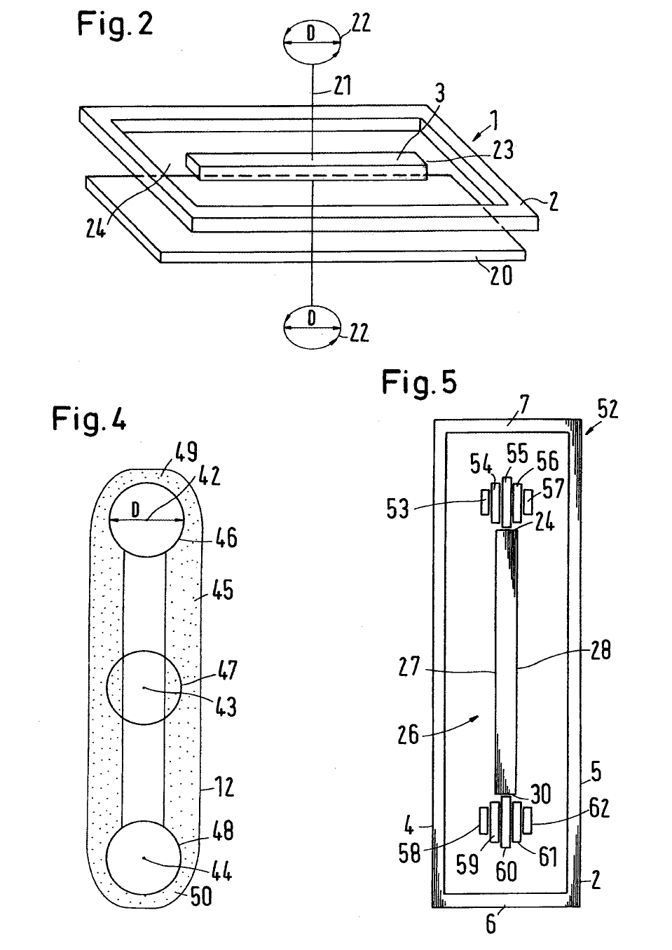

FIG. 2 shows a disposition according to the invention of the magnet configuration 1 relative to a target 20. This target 20 is rectangular and its dimensions are slightly larger than those of the magnet configuration 1. North pole 2 and south pole 3 are connected with one another via a, not shown, yoke plate such that the relative position of the south pole 3 with respect to the north pole 2 is always in conformation.

To make the sputtering of the target 20 more uniform, an imaginary axis 21 through the south pole-north pole configuration is rotated on a circle 22 with the diameter D.

The magnet system 1 consequently is moved such that each of its points describes a circle with the same diameter D. The magnet system 1 and the target 20 are located in planes which are oriented parallel to one another.

If a voltage is applied on the, not shown, cathode, a plasma is ignited. Hereby the plasma tube 12, depicted in FIG. 1 and self-contained, is formed whose shape is determined by the magnetic field of the magnet configuration 1.

When moving the magnet configuration 1 relative to target 20 the plasma tube 12 is also moved and thus guided over a large portion of the target surface which herein is stationary. The plasma tube 12 consequently also sweeps over areas of target 20 which in static operation would not be sputtered.

To avoid the redeposition of the eroded target material onto the target surface, each site of the surface of target 20 should be covered for a certain length of time by the plasma tube 12.

The magnet configuration 1 depicted in FIGS. 1 and 2 still has the disadvantage that an intensified material erosion occurs in the curve region 23, 24 of the magnet system 1. Thereby in the target 20 a hole results in this curve region 23, 24.

To avoid this hole, the inner magnet pole is modified in the manner shown in FIG. 3.

In the case of the magnet configuration 25 depicted in FIG. 3 the outer magnet 2 is structured like the outer magnet according to FIG. 1.

However, the inner magnet 26 has a different form. While it also comprises a bar with two long sides 27, 28 and two short sides 24, 30, the long sides 27, 28 are shorter than is the case with the inner magnets 3 according to FIG. 1.

The short sides 24, 30 are adjoined in each instance by five small bar magnets 31 to 35 or 36 to 40, respectively, which together form essentially a circular body, such that the inner magnet pole has approximately the form of a bone. The small bar magnets 33 and 38 extend parallel to the short sides 7, 6 of the outer magnet pole, while the small bar magnets 32, 34 or 37, 39 extend parallel to the long sides 4, 5 of the outer magnet pole. The small bar magnets 31, 35 or 36, 40 establish a connection between the bar magnets 32, 34 or 37, 39 and the short sides 24, 30 of the inner magnet pole 26. They are approximately disposed at an angle of 45 degrees relative to the longitudinal axis of the inner magnet 26.

The plasma tube 45 resulting due to the magnet configuration 25 is once again depicted in FIG. 4 without magnet configuration 25.

The illustration of FIG. 4 serves for an explanation of the manner in which the quantity of the material eroded from a target 20 with the circular movement of the magnet configuration 25 above the target 20 can be calculated at a specific site 42, 43, 44 of the target.

For this purpose along a circular path 46 with diameter D the plasma density is mathematically integrated (cf. in this connection Shunji Ido, Koji Nakamura: Computational Studies on the Shape and Control of Plasmas in Magnetron Sputtering Systems, Jpn. J. Appl. Phys. 32; 5698-5702, 1993). A closed contour path integral is formed therein. For the circular path 46 this integration yields the value zero since no plasma is found within the circular path 46.

In the case of the circular path 47 a certain positive value results for the plasma density since here the plasma tube 45 penetrates into the circular path 47. For the circular path 48 results again, as was the case with the circular path 46, the value zero.

Thereby that the plasma in the curve region 49, 50 is constricted, the holes in the target 20 are avoided, which occur when utilizing a magnet configuration 1 according to FIG. 1.

The constriction should be large enough for the plasma tube 45 to be guided on the circular path 46 around the curve, wherein the inner side of the plasma tube 45 describes a circular path with diameter D, which corresponds to the distance D shown in FIG. 1.

Such a constriction can be attained through a very wide magnet or through several narrow magnets arranged next to one another.

FIG. 5 illustrates such a magnet configuration 52. Instead of the bar magnets 31 to 35 or 36 to 40 according to FIG. 3 and disposed in a quasi-circle, in the magnet configuration 52 in FIG. 5 five bar magnets 53 to 57 or 58 to 62, respectively, are in each instance disposed at the short sides 29, 30 of the magnet pole 26, and specifically parallel to the long sides 4, 5 of the north pole 2.

The central magnet 55 or 60 is in each case the largest, while the laterally succeeding magnets 54, 53; 56, 57 or 58, 59; 61, 62 become increasingly shorter toward the outside.

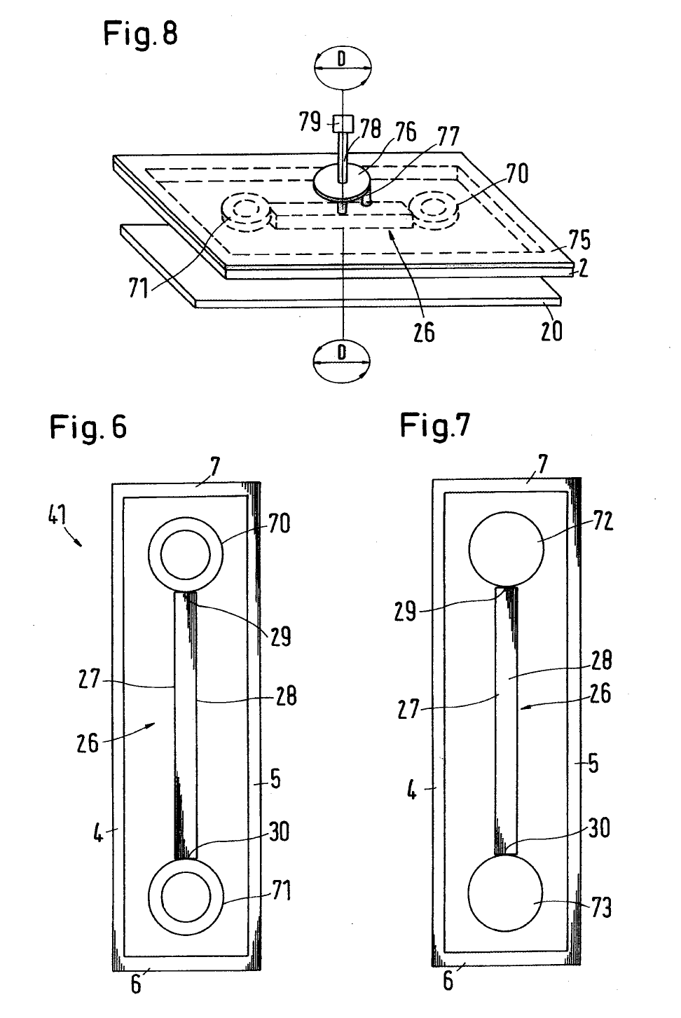

FIG. 6 shows a further variant of the inner magnet pole 26 in a magnet configuration 41. Each end 29, 30 of bar 26 is herein adjoined in each instance by a magnet ring 70, 71.

In the variant of FIG. 7 a disk 72, 73 is provided instead of a ring.

In FIG. 8 the magnet configuration according to FIG. 6 is shown once again together with a target 20 and a schematic drive. Herein is evident a yoke plate 75 above the two magnet poles 26, 2. By 76 is denoted a drive wheel on whose periphery a pin 77 is located which is directed downwardly and is connected with the yoke plate 75. The drive wheel 76 is connected with an upwardly directed shaft 78, which is driven by a motor 79.

If the pin 77 is disposed at a distance D/2 from the center of the driving wheel 76 and the motor 79 is started up, the yoke plate 75 moves with the magnet system in the manner already described, i.e. such that each point of the yoke and of the magnet system moves on a circular path. The pin 77 is herein not rigidly connected with the yoke plate 75 but rather inserted into a hole of this yoke plate 75 where it can rotate and in this way prevents that the yoke plate 75 rotates as a whole about the shaft 78. The geometric orientation (x-, y-axis) of the short and long sides of the yoke plate 75 remains unchanged during the rotational movement.

It is not necessary for the pin 77 to project into an opening in the yoke plate 75 itself. It is also feasible to provide for this purpose an additional plate connected with the yoke plate 75. Any other drive, which effects the desired movement of the magnet configuration relative to the target (cf. EP 0 918 351 A1, FIG. 6) can also be utilized. It is only essential that each point on the magnet configuration describes a movement on a circumference with diameter D.

The magnets, which form the ends of the bar-shaped inner magnet pole 26, are preferably implemented such that their magnetic field lines form relative to the surface of the target 20 an angle greater than 20 degrees.

1. Sputter magnetron with a planar target and a planar magnet configuration, wherein the magnet configuration comprises a bar-shaped first magnet pole and a frame-shaped second magnet pole and wherein target and magnet configuration can be moved relative to one another such that each point of the target moves relative to the magnet configuration on a circle, characterized in that the ends of the bar-shaped first magnet pole (3, 26) are expanded in the form of a circle.

2. Sputter magnetron as claimed in claim 1, characterized in that the expanded ends have a diameter D, which corresponds at least to the mean distance between two parallel arms (12, 13) of a plasma tube, which develops during a sputter operation between the first and the second magnet pole (3, 2).

3. Sputter magnetron as claimed in claim 1, characterized in that the ends of the bar-shaped first magnet pole (3, 26) are each formed of several small bar magnets.

4. Sputter magnetron as claimed in claim 3, characterized in that each end is comprised of a bar magnet (33, 38) extending parallel to the short side (6, 7) of the frame-shaped magnet pole (2), two bar magnets (32, 34; 37, 39) extending parallel to the long side (4, 5), and two bar magnets (31, 35) extending at an angle of approximately 45 degrees to the longitudinal axis of the first bar-shaped magnet pole (26).

5. Sputter magnetron as claimed in claim 4, characterized in that the small bar magnets (33, 38, 32, 34; 37, 39, 31, 35) are a spatially disposed series one after the other.

6. Sputter magnetron as claimed in claim 3, characterized in that each end is comprised of several bar magnets (53-57) extending parallel to the long sides (4, 5) of the frame-shaped magnet pole (2), whose length decreases in the direction toward these long sides (4, 5).

7. Sputter magnetron as claimed in claim 1, characterized in that each end of the bar-shaped first magnet pole (3, 26) is comprised of a ring magnet (70, 71).

8. Sputter magnetron as claimed in claim 1, characterized in that each end of the bar-shaped magnet pole (3, 26) is comprised of a circular disk (72, 73).

9. Sputter magnetron as claimed in claim 1, characterized in that the magnetic field lines of the circularly expanded ends of the first magnet pole (3, 26) have an angle relative to the surface of a target (20) which is greater than 20 degrees.
